(19) United States
(12) Patent Application Publication
(10) Pub. No.: US 2017/0003334 A1
(43) Pub. Date: Jan. 5, 2017

(54) RAPID ONLINE DIAGNOSIS METHOD OF OPEN-CIRCUIT FAULT FOR HIGH-POWER RECTIFIER

(71) Applicants: XJ GROUP CORPORATION, Xuchang (CN); XUCHANG XJ SOFTWARE TECHNOLOGIES LTD, Xuchang (CN); XJ ELECTRIC CO.,LTD, Xuchang (CN); XI'AN JIAOTONG UNIVERSITY, Xi'an (CN); STATE GRID CORPORATION OF CHINA, Beijing (CN)

(72) Inventors: Xing Liu, Xuchang (CN); Xiaobo Wang, Xuchang (CN); Ruizhi Jiang, Xuchang (CN); Yuanhang Yang, Xuchang (CN); Guobing Song, Xuchang (CN); Xu Zhu, Xuchang (CN); Yanhua Zhang, Xuchang (CN)

(21) Appl. No.: 15/076,160

(22) Filed: Mar. 21, 2016

(30) Foreign Application Priority Data
Jun. 30, 2015 (CN) 201510385410.7

(51) Int. Cl. G01R 31/02; H02H 7/125

(52) U.S. Cl. CPC G01R 31/025; H02H 7/125

(57) ABSTRACT

The invention relates to rapid online diagnosis method of high-power rectifier open-circuit fault, including: 1) collecting actual output direct current value i_{d}(t₀) and three phase input electric current instantaneous values iₐ(t₀), i_{b}(t₀) and i_{c}(t₀) of rectifier at t₀ moment, and calculating theoretical output direct current value i_{d}′ of the rectifier according to iₐ(t₀), i_{b}(t₀) and i_{c}(t₀); 2) comparing i_{d}′ (t₀) and i_{d}(t₀), when i_{d}′ (t₀) is not more than k1×i_{d}(t₀), comparing absolute value of maximal three phase input electric current instantaneous value and pre-set threshold value A₁, if the maximal three phase input electric current instantaneous value is not less than A₁, the rectifier appears open-circuit fault. The inventive method is simple, with no complicated step for performing fault diagnosis, of course, the short fault diagnosis period and tripping protection occupation time is short, but it also can protect the rectifier effectively and prevent equipment damage from longtime working under fault condition.

### TECHNICAL FIELD

The present invention relates to fault diagnosis of power electronic equipment and relaying protection technical field, in particular to rapid online diagnosis method of open-circuit fault for high-power rectifier.

### BACKGROUND

With wide using of high-power rectifier device in the fields of power transmission, chemical industry, metallurgy, railway, and other industries, problem of power electronic equipment has become more prominent. The fault of rectifier mainly refers to fault of switching tube of rectifier bridge. Switching tube itself reverse breakdown or insulating layer of bridge arm damage and other reasons, these will cause short circuit of the switching tube, resulting in rapid increasing electric current, sharp decreasing turn-on voltage drop, and serious damaging equipment to make system paralysis; when the switching tube occurs poor connection or over current burn, and other circumstances, thus these can cause open circuit of the switching tube, maybe lead to other switching tubes current out-of-limit, and the output current voltage ripple becomes large, thus affecting normal operation of equipment, these are the most common fault and hazard of rectifier.

Once fault occurs, if recognition for fast processing not timely, thus causing range from economic losses to personnel life safety. Currently, fault diagnosis research has in-depth study in terms of power electronic equipment, the primary method used to determine rectifier fault in China and abroad is: spectral analysis method, dictionary database diagnostic method, pattern recognition, neural network method, and other aspects method.

The spectral analysis method includes extracting time-domain signal of fault, and performing analysis of time-domain signal changing to frequency domain through using Fourier change. The dictionary database diagnostic method need to perform vast numerical simulation and experiment to obtain fault value and characteristic value, thus these is difficulty realized in real system. The neural network method has effects of strong estimating capability and artificial intelligence modeling capability, but its training sample is not easy to obtain, diagnostic capability is not strong, network weight manifestation pattern is fuzzy, and other shortcomings led to limited practical application scope of the neural network method. And most of above several methods having strong dependence on protection system only study open fault diagnosis, not only monitoring cost is increased, but also can not response fault condition quickly, particularly for developing fault, for example the single-tube straight fault, which will lead to overcurrent burn of the same side of other switches if protection system is disabled.

### DESCRIPTION

The purpose of the present invention is to provide a rapid online diagnosis method of open-circuit fault for high-power rectifier for solving many existent defects of fault diagnosis method of conventional rectifier.

For achieving the above purpose, the present invention comprises rapid online diagnosis method of open-circuit fault for high-power rectifier, the rapid online diagnosis method includes the steps of:

1) collecting present actual value of output direct current for the rectifier and present instantaneous value of three phase input electric current for the rectifier, and calculating present theoretical value of output direct current for the rectifier according to the present instantaneous value of three phase input electric current;

2) comparing the actual value of output direct current with the theoretical value of output direct current, when the theoretical value of output direct current is not more than kg times of the actual value of output direct current, instantaneous value of a direct current component in the three phase input electric current is calculated, then compares absolute value of maximal one in instantaneous value of the direct ent component with a first pre-set threshold value A₁, when the absolute value of maximal one is not less than the first pre-set threshold value A₁, the rectifier is diagnosed to have open-circuit fault;

wherein k1 is a measured confidence coefficient; A₁=m×A, m is a constant, and A is a value of a direct current component for a switching tube under rated condition.

Preferably, when the absolute value of maximal one in instantaneous value is not less than the first pre-set threshold value A₁, a direct current component of three phase input electric current from present moment to one power frequency period ended is calculated, then compares absolute value of maximal one of three direct current component with second pre-set threshold value A₂, when the absolute value of maximal one is not less than the second pre-set threshold value A₂, the rectifier is diagnosed to have open-circuit fault for single-tube; otherwise, the rectifier is diagnosed to have open-circuit fault for inlet wire of single phase alternating current; wherein the second pre-set threshold value A₂=n×A, n is a constant.

Preferably, when the absolute value of maximal one is not less than the second pre-set threshold value A₂, corresponding phase of absolute value of maximal one fault phase.

Preferably, when corresponding direct current component of input current of the fault phase is positive value, lower arm tube of the fault phase is diagnosed to have open-circuit fault; when corresponding direct current component of input current of the fault phase is negative value, upper arm tube of the fault phase is diagnosed to have open-circuit fault.

Preferably, when the rectifier is diagnosed to have open-circuit fault for inlet wire of single phase alternating current, calculation formulas for calculating three phase fundamental current amplitude Iₘₐ, I_{mb} and I_{mc} are as follows:

$$\{ \begin{matrix}x = \frac{2}{N} {\sum }_{k = 1}^{N} {i}_{a} ( k ) sin ( \frac{2 π k}{N} ) \\ y = \frac{2}{N} {\sum }_{k = 1}^{N} {i}_{a} ( k ) cos ( \frac{2 π k}{N} ) \\ {I}_{ma} = \sqrt{{x}^{2} + {y}^{2}}\end{matrix} \\ \{ \begin{matrix}x = \frac{2}{N} {\sum }_{k = 1}^{N} {i}_{b} ( k ) sin ( \frac{2 π k}{N} ) \\ y = \frac{2}{N} {\sum }_{k = 1}^{N} {i}_{b} ( k ) cos ( \frac{2 π k}{N} ) \\ {I}_{mb} = \sqrt{{x}^{2} + {y}^{2}}\end{matrix} \\ \{ \begin{matrix}x = \frac{2}{N} {\sum }_{k = 1}^{N} {i}_{c} ( k ) sin ( \frac{2 π k}{N} ) \\ y = \frac{2}{N} {\sum }_{k = 1}^{N} {i}_{c} ( k ) cos ( \frac{2 π k}{N} ) \\ {I}_{m c} = \sqrt{{x}^{2} + {y}^{2}}\end{matrix}$$

wherein iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀, (t₀+T)] time interval; supposing that the fault phase amplitude is I_{mg}, I_{mg}=min(Iₘₐ, I_{mb}, I_{mc}).

Preferably, when the theoretical value of output direct current is more than k1 times of the actual value of output direct current, the rectifier is diagnosed to have short circuit fault of switching tube.

Preferably, when the theoretical value of output direct current is more than k1 times of the actual value of output direct current, direct current component in the three phase input electric current from present moment to one power frequency period ended is calculated, if plus-minus of one of direct current component is different from the other two direct current components, corresponding phase of the direct current component is fault phase.

Preferably, calculation formula of the theoretical value of output direct current for the rectifier at present moment is as follow:

i_{d}′(t₀)=(|iₐ(t₀)|+|i_{b}(t₀)|+|i_{c}(t₀)|)/2

wherein t₀ is present moment, i_{d}′ (t₀) is the theoretical value of output direct current for rectifier at present moment, and iₐ(t₀), i_{b}(t₀) and i_{c}(t₀) are instantaneous values of three phase input electric current at present moment; wherein calculation formulas of instantaneous value of three phase input electric current are as follows:

$$\{ \begin{matrix}{id}_{a} ( {t}_{0} ) = \frac{1}{N} {\sum }_{k = 1}^{N} {i}_{a} ( k ) \\ {id}_{b} ( {t}_{0} ) = \frac{1}{N} {\sum }_{k = 1}^{N} {i}_{b} ( k ) \\ {id}_{c} ( {t}_{0} ) = \frac{1}{N} {\sum }_{k = 1}^{N} {i}_{c} ( k )\end{matrix}$$

wherein t₀ is present moment, iₐ(t₀), i_{b}(t₀) and i_{c}(t₀) are the instantaneous values of three phase input electric current, iₐ(k) is electric current of the k-th sampling point of phase A, i_{b} (k) is electric current of the k-th sampling point of phase B, i_{c}(k) is electric current of the k-th sampling point of phase C, N is the total number of sampling point in each phase, and N sampling points are obtained within [t₀; (t₀+T)] time interval, T is power frequency period of input current for the rectifier.

Preferably, calculation formulas of direct current component of three phase input electric current are as follows:

$$\{ \begin{matrix}{id}_{a} ( {t}_{0} + T ) = \frac{1}{N} {\sum }_{k = 1}^{N} {i}_{a} ( k ) \\ {id}_{b} ( {t}_{0} + T ) = \frac{1}{N} {\sum }_{k = 1}^{N} {i}_{b} ( k ) \\ {id}_{c} ( {t}_{0} + T ) = \frac{1}{N} {\sum }_{k = 1}^{N} {i}_{c} ( k )\end{matrix}$$

wherein t₀ is present moment, idₐ(t₀+T), id_{b}(t₀+T) and id, id_{c}(t₀+T) are direct current components of three phase input electric current, T is power frequency period of input current for the rectifier, iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀, (t₀+T)] time interval.

Preferably, m is 0.25, and n is 0.5.

The rectifier open-circuit fault diagnosis method provided by present invention calculates the present theoretical value of output direct current for the rectifier according to the instantaneous value of three phase input electric current at the present moment, compares with present actual value of output direct current for the rectifier, when the present theoretical value of output direct current is not more than pre-set times of the present actual value of output direct current, and satisfies other decision conditions at the same time, we judges if rectifier appears the open-circuit fault.

The advantages of the present invention are as follows.

1. The inventive method has the advantage of simple steps fix fault diagnosis, accordingly, short fault diagnosis period, and short time from the beginning of judging the fault to end, in other words, short time of tripping operation protection when the rectifier is diagnosed to appear fault. The method can protect the rectifier effectively and prevent equipment damage brought by longtime working under fault conditions.

2. With high diagnostic accuracy and high maintenance reliability, the inventive diagnosis method can judge specific fault type open-circuit fault, and adopt corresponding maintenance measure aiming at specific fault in subsequent maintenance procedure.

### BRIEF DESCRIPTION OF THE DRAWINGS

FIG. 1 is the rectifier structure view of embodiment 1 of the present invention;

FIG. 2 is the process diagram of embodiment 1 of the present inventio.

### DETAILED DESCRIPTION

Detailed illustrations combining with Figures of the present invention are as follow:

### Embodiment 1

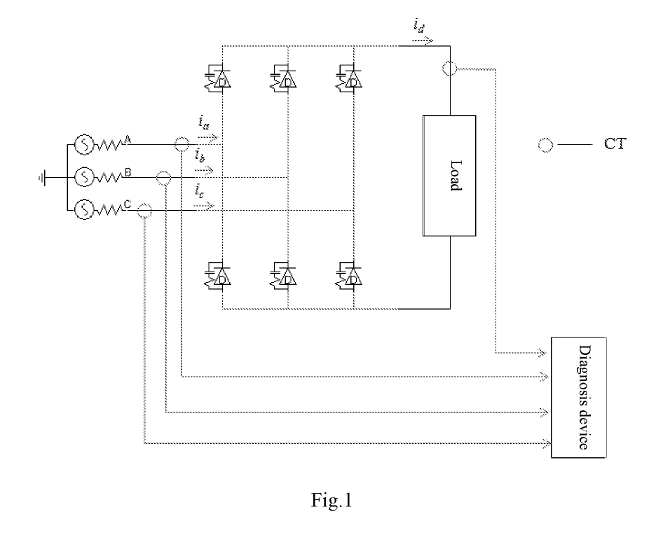

As shown in FIG. 1, the rectifier is a full-bridge rectifier, which comprises three upper bridge arms and three lower bridge arms. The rectifier is three-phase alternating current input which are phase A, phase B and phase C. In three-phase alternating current input of the rectifier, each phase input contains two bridge arm divided into upper bridge arm and lower bridge arm, each bridge arm cascades a thyristor and the rectifier comprises six thyristors. Circuit of three-phase input for the rectifier is provided with three current monitoring points including corresponding current collection. Circuit of direct-current output for the rectifier is provided with current sensor for collecting direct-current. Three current monitoring points of input end and current collecting points of output end used for deciding the rectifier fault are connected with diagnostic device.

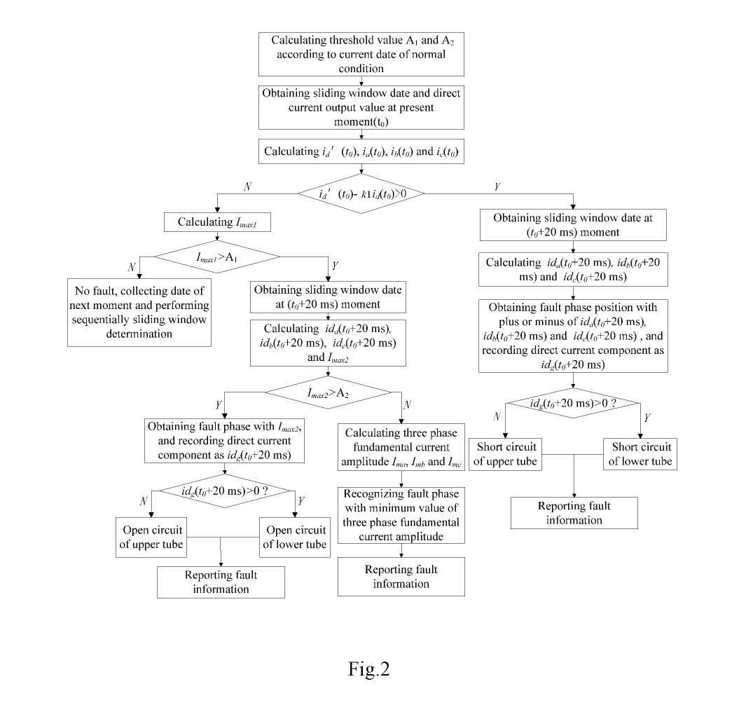

Supposing t₀ is fault determining moment, as shown in FIG. 2, during fault diagnosis operation, the current collecting device of circuit of three phase input for the rectifier collects instantaneous value of three phase input electric current iₐ(t₀), i_{b}(t₀) and i_{c}(t₀) at t₀ moment, and transfers iₐ(t₀), i_{b}(t₀) and i_{c}(t₀) to diagnostic device, meanwhile, the current collecting device of output circuit for the rectifier collects actual output direct current i_{d} (t₀) at t₀ moment, and transfers i_{d} (t₀) to the diagnostic device. The diagnostic device calculates theoretical output current i_{d}′ (t₀) of the rectifier and compares i_{d}′ (t₀) and k1×i_{d} (t₀) according to the instantaneous value iₐ(t₀), i_{b}(t₀) and i_{c}(t₀) and formula of i_{d}′ (t₀)=(|iₐ(t₀)|+|i_{b}(t₀)|+|i_{c}(t₀)|)/2, wherein k1 whose value is within [1, 2] a measured confidence coefficient based on practical condition.

When i_{d}′ (t₀)>k1×i_{d} (t₀), the rectifier is diagnosed to have a short circuit fault in thyristor. Then from moment t₀ to next power frequency period, that is moment t₀+20 ms, we calculate direct current components idₐ(t₀+20 ms), id_{b}(t₀+20 ms) and id_{c}(t₀+20 ms) of three-phase input current within one cycle with data window of [t₀, t₀+20 ms], wherein calculation formulas are as follows:

$$\{ \begin{matrix}{id}_{a} ( {t}_{0} + 20 ms ) = \frac{1}{N} {\sum }_{k = 1}^{N} {i}_{a} ( k ) \\ {id}_{b} ( {t}_{0} + 20 ms ) = \frac{1}{N} {\sum }_{k = 1}^{N} {i}_{b} ( k ) \\ {id}_{c} ( {t}_{0} + 20 ms ) = \frac{1}{N} {\sum }_{k = 1}^{N} {i}_{c} ( k )\end{matrix}$$

wherein t₀ is present moment, iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀, t₀+T] time interval. Then, determining the plus-minus relation among direct current components of three-phase input current, if plus-minus of one direct current component is different from the other two direct current components, corresponding phase is fault phase, in addition, when deciding corresponding direct current component of the fault phase is positive value, the lower arm tube of fault phase is diagnosed to appear short circuit fault; when corresponding direct current component of the fault phase is negative value, the upper arm tube of fault phase is diagnosed to appear short circuit fault. For example, judging the plus-minus relation of direct current components among idₐ(t₀+20 ms), id_{b}(t₀+20 ms) and id_{c}(t₀+20 ms), if id_{b}(t₀+20 ms) is positive value, idₐ(t₀+20 ms) and id_{c}(t₀+20 ms) is negative value, phase B is fault phase, and the lower arm tube of phase B is diagnosed to appear short circuit fault.

When i_{d}′ (t₀)≦k1×i_{d}(t₀), there is no short circuit fault for the thyristor in the rectifier, calculating direct current components idₐ(t₀), id_{b}(t₀) and id_{c}(t₀) of three phase input current, wherein calculation formulas are as follows:

$$\{ \begin{matrix}{id}_{a} ( {t}_{0} ) = \frac{1}{N} {\sum }_{k = 1}^{N} {i}_{a} ( k ) \\ {id}_{b} ( {t}_{0} ) = \frac{1}{N} {\sum }_{k = 1}^{N} {i}_{b} ( k ) \\ {id}_{c} ( {t}_{0} ) = \frac{1}{N} {\sum }_{k = 1}^{N} {i}_{c} ( k )\end{matrix}$$

wherein t₀ is present moment, iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀−T, t₀] time interval, T is power frequency period of rectifier input current. Absolute value of maximal one among idₐ(t₀), id_{b}(t₀) and id_{c}(t₀) is recorded as Iₘₐₓ₁, then compare Iₘₐₓ₁ and pre-set threshold value A₁, when Iₘₐₓ₁<A₁, the rectifier is diagnosed to have no open-circuit fault; when Iₘₐₓ₁≧A₁, the rectifier is diagnosed to have open-circuit fault such as the open-circuit fault of FIG. 2.

Specifically, for determination of open-circuit fault for the rectifier:

Direct current components idₐ(t₀+20), id_{b}(t₀+20 ms) and id_{c}(t₀+20 ms) of three-phase input current are calculated through above mentioned formulas, absolute value of maximal one among idₐ(t₀+20 ms), id_{b}(t₀+20 ms) and id_{c}(t₀+20 ms) is recorded as Iₘₐₓ₂, then comparing Iₘₐₓ₂ to have single-tube open-circuit fault, and absolute value corresponding of fault direct current component in three direct current component is maximum. When corresponding direct current component of the fault phase is positive value, the lower arm tube of fault phase is diagnosed to have short circuit fault; when corresponding direct current component of the fault phase is negative value, the upper arm tube of fault phase is diagnosed to have short circuit fault.

When if Iₘₐₓ₂<A₂, the rectifier is diagnosed to have open-circuit fault of single phase alternating current inlet wire, at the moment, electric current of the fault phase is zero, three phase fundamental current amplitudes Iₘₐ, I_{mb} and I_{mc} are obtained through Fourier analysis with [t₀, t₀+20 ms] data window, and calculation formulas of Iₘₐ, I_{mb} and I_{mc} are as follows:

$$\{ \begin{matrix}x = \frac{2}{N} {\sum }_{k = 1}^{N} {i}_{a} ( k ) sin ( \frac{2 π k}{N} ) \\ y = \frac{2}{N} {\sum }_{k = 1}^{N} {i}_{a} ( k ) cos ( \frac{2 π k}{N} ) \\ {I}_{ma} = \sqrt{{x}^{2} + {y}^{2}}\end{matrix} \\ \{ \begin{matrix}x = \frac{2}{N} {\sum }_{k = 1}^{N} {i}_{b} ( k ) sin ( \frac{2 π k}{N} ) \\ y = \frac{2}{N} {\sum }_{k = 1}^{N} {i}_{b} ( k ) cos ( \frac{2 π k}{N} ) \\ {I}_{mb} = \sqrt{{x}^{2} + {y}^{2}}\end{matrix} \\ \{ \begin{matrix}x = \frac{2}{N} {\sum }_{k = 1}^{N} {i}_{c} ( k ) sin ( \frac{2 π k}{N} ) \\ y = \frac{2}{N} {\sum }_{k = 1}^{N} {i}_{c} ( k ) cos ( \frac{2 π k}{N} ) \\ {I}_{m c} = \sqrt{{x}^{2} + {y}^{2}}\end{matrix}$$

wherein I_{mg} is fault phase amplitude, I_{mg}=min(Iₘₐ, I_{mb}, I_{mc}).

After the diagnostic device performs diagnosis completely, diagnosis result of fault character and position for the rectifier is uploaded.

In the present invention, A₁=m×A, A₂=n×A, wherein A is direct current component of single-tube under standard running condition, direct current component of each thyristor is the same and unchangeable under standard running condition; m and n are constants according to specific condition, in the embodiment, specific embodiment mode is provided, A₁=0.25A, A₂=0.5A. because threshold values A₁ and A₂ are connected with direct current component of single-tube under standard running condition, and not connected with all current value generated under fault, so, so long as m and n are sure, threshold value A₁ and A₂ are fixed values, A₁ and A₂ can be calculated in advance, and used in fault diagnosis; m is included in 0.1-0.5, and n is included in 0.5-0.9.

Rectifier fault diagnostic method provided by of the present invention only needs to measure instantaneous value of three-phase input current at t₀ moment to obtain theoretical value of output direct current for the rectifier. The method obtains direct current component of three phase input current by calculating in-different data window, and then obtains character and position of the rectifier fault-with the advantage of simple convenient operation, low cost, reliable performance, no need of measuring voltage, and decrease of testing cost. Meanwhile, in the process of determination, there is no complicated mathematical function operation, a small amount of calculation, and capable of real-time monitoring, rapid reacting fault, recognizing fault within 20 ms of fault occurrence, and locating fault within 40 ms. The present invention not only lays the foundation for processing fault accurately and timely, but also brings convenience for maintenance work, and a huge economic benefit.

In the above embodiment, calculation formula of theoretical value of output direct current i_{d}′ (t₀) at t₀ moment is as follow:

i_{d}′(t₀)=(|iₐ(t₀)|+|i_{b}(t₀)|+|i_{c}(t₀)|)/2

wherein i_{d}′ (t₀) can use the maximum absolute value among iₐ(t₀), i_{b}(t₀) and i_{c}(t₀).

In the above embodiment, because frequency of power frequency alternating current is 50 Hz, one power frequency period T is 20 ms, but in others embodiments, power frequency period T is different according to different frequency of alternating current.

### Embodiment 2

In the embodiment 1, fault diagnosis method of the rectifier includes: performing big-small diagnosis of i_{d}′ (t₀) and k1×i_{d} (t₀), When i_{d}′ (t₀) is more than k1×i_{d} (t₀), the rectifier is diagnosed to have short circuit fault for the thyristor, When i_{d}′ (t₀) is not more than k1×i_{d} (t₀), and Iₘₐₓ₁ is not less than the pre-set threshold value A₁, rectifier is diagnosed to have open-circuit fault. The embodiment 2 only performs diagnosis of short circuit fault for the thyristor, that is, only including the step of: when i_{d}′ (t₀) is more than k1×i_{d} (t₀), the rectifier is diagnosed to have short circuit fault of thyristor, others specific steps are detailedly illustrated in the embodiment 1, and-not repeated here.

### Embodiment 3

In the embodiment 1, fault diagnosis method of rectifier includes: performing big-small diagnosis of i_{d}′ (t₀) and k1×i_{d} (t₀), When i_{d}′ (t₀) is more than k1×i_{d} (t₀), the rectifier is diagnosed to have short circuit fault for the thyristor, when i_{d}′ (t₀) is not more than k1×i_{d} (t₀), and Iₘₐₓ₁ is not less than the pre-set threshold value A₁, the rectifier is diagnosed to have open-circuit fault. The embodiment 3 only performs diagnosis of open-circuit fault for the thyristor, that is, only including the steps of when i_{d}′ (t₀) is not more than k1×i_{d}(t₀), and Iₘₐₓ₁ is not less than the pre-set threshold value A₁, the rectifier is diagnosed to have open-circuit fault, others specific steps are detailedly illustrated in the embodiment 1, and-not repeated here.

Although the embodiments of the present invention have been disclosed above, they are not limited to the applications previously mentioned in the specification and embodiments, and can be applied in various fields suitable for the present invention. For ordinary skilled person in the field, other various changed model, formula and parameter e may be easily achieved without creative work according to instruction of the present invention, changed, modified and replaced embodiments without departing the general concept defined by the claims and their equivalent are still included in the present invention. The present invention is not limited to particular details and illustrations shown and described herein.

1. A rapid online diagnosis method of open-circuit fault for high-power rectifier, being characterized in that, the rapid online diagnosis method includes the steps of:
1) collecting present actual value of output direct current for the rectifier and present instantaneous value of three phase input electric current for the rectifier, and calculating present theoretical value of output direct current for rectifier according to the present instantaneous value of three phase input electric current; and
2) comparing the actual value of output direct current with the theoretical value of output direct current, when the theoretical value of output direct current is not more than k1 times of the actual value of output direct current, instantaneous value of a direct current component in the three phase input electric current is calculated, then comparing absolute value of maximal one in instantaneous value of the direct current component with a first pre-set threshold value A₁, when the absolute value of maximal one is not less than the first pre-set threshold value A₁, the rectifier is diagnosed to have open-circuit fault;
wherein k1 is a measured confidence coefficient; A₁=m×A, m is a constant, and A is a value of a direct current component for a switching tube under rated condition.

2. The rapid online diagnosis method of open-circuit fault for high-power rectifier of claim 1, being characterized in that:
when the absolute value of maximal instantaneous value is not less than the first pre-set threshold value A₁, a direct current component of three phase input electric current from present moment to one power frequency period ended is calculated, then compares absolute value of maximal one among three direct current components with the second pre-set threshold value A₂,
when the absolute value of maximal one is not less than the second pre-set threshold value A₂, the rectifier is diagnosed to have open-circuit fault for single-tube; otherwise, the rectifier is diagnosed to have open-circuit fault for inlet wire of single phase alternating current; wherein the second pre-set threshold value A₂=n×A, n is a constant.

3. The rapid online diagnosis method of open-circuit fault for high-power rectifier of claim 2, being characterized in that: when the absolute value of maximal one is not less than the second pre-set threshold value A₂, corresponding phase of absolute value of maximal one is fault phase.

4. The rapid online diagnosis method of open-circuit fault for high-power rectifier of claim 3, being characterized in that: when corresponding direct current component of input current of the fault phase is positive value, lower arm tube of the fault phase is diagnosed to have open-circuit fault; when corresponding direct current component of input current of the fault phase is negative value, upper arm tube of the fault phase is diagnosed to have open-circuit fault.

5. The rapid online diagnosis method of open-circuit fault for high-power rectifier of claim 2, being characterized in that: when the rectifier is diagnosed to have open-circuit fault for inlet wire of single phase alternating current, calculation formulas for calculating three phase fundamental current amplitudes Iₘₐ, I_{mb} and I_{mc} are as follows:
$$\{ \begin{matrix}x = \frac{2}{N} {\sum }_{k = 1}^{N} {i}_{a} ( k ) sin ( \frac{2 π k}{N} ) \\ y = \frac{2}{N} {\sum }_{k = 1}^{N} {i}_{a} ( k ) cos ( \frac{2 π k}{N} ) \\ {I}_{ma} = \sqrt{{x}^{2} + {y}^{2}}\end{matrix} \\ \{ \begin{matrix}x = \frac{2}{N} {\sum }_{k = 1}^{N} {i}_{b} ( k ) sin ( \frac{2 π k}{N} ) \\ y = \frac{2}{N} {\sum }_{k = 1}^{N} {i}_{b} ( k ) cos ( \frac{2 π k}{N} ) \\ {I}_{mb} = \sqrt{{x}^{2} + {y}^{2}}\end{matrix} \\ \{ \begin{matrix}x = \frac{2}{N} {\sum }_{k = 1}^{N} {i}_{c} ( k ) sin ( \frac{2 π k}{N} ) \\ y = \frac{2}{N} {\sum }_{k = 1}^{N} {i}_{c} ( k ) cos ( \frac{2 π k}{N} ) \\ {I}_{m c} = \sqrt{{x}^{2} + {y}^{2}}\end{matrix}$$
wherein iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀, (t₀+T)] time interval; if fault phase amplitude is supposed with I_{mg}, I_{mg}=min(Iₘₐ, I_{mb}, I_{mc}).

6. The rapid online diagnosis method of open-circuit fault for high-power rectifier of claim 1, being characterized in that: when the theoretical value of output direct current is more than k1 times of the actual value of output direct current, the rectifier is diagnosed to have short circuit fault of switching tube.

7. The rapid online diagnosis method of open-circuit fault for high-power rectifier of claim 6, being characterized in that: when the theoretical value of output direct current is more than k1 times of the actual value of output direct current, direct current component in the three phase input electric current from present moment to one power frequency period ended is calculated, if plus-minus of one direct current component is different from the other two direct current components, corresponding phase of the direct current component is fault phase.

8. The rapid online diagnosis method of open-circuit fault for high-power rectifier of claim 1, being characterized in that: calculation formula of the theoretical value of output direct current for the rectifier at present moment is as follow:
i_{d}′(t₀)=(|iₐ(t₀)|+|i_{b}(t₀)|+|i_{c}(t₀)|)/2
wherein t₀ is present moment, i_{d}′ (t₀) is the theoretical value of output direct current for rectifier at present moment, and iₐ(t₀), i_{b}(t₀) and i_{c}(t₀) are instantaneous values of three phase input electric current at present moment; wherein calculation formulas of instantaneous value of three phase input electric current are as follows:
$$\{ \begin{matrix}{id}_{a} ( {t}_{0} ) = \frac{1}{N} {\sum }_{k = 1}^{N} {i}_{a} ( k ) \\ {id}_{b} ( {t}_{0} ) = \frac{1}{N} {\sum }_{k = 1}^{N} {i}_{b} ( k ) \\ {id}_{c} ( {t}_{0} ) = \frac{1}{N} {\sum }_{k = 1}^{N} {i}_{c} ( k )\end{matrix}$$
wherein t₀ is present moment, iₐ(t₀), i_{b}(t₀) and i_{c}(t₀) are the instantaneous values of three phase input electric current, iₐ(k) is electric current of the k-th sampling point of phase A, i_{b}(k) is electric current of the k-th sampling point of phase B, i_{c}(k) is electric current of the k-th sampling point of phase C, N is the total number of sampling point in each phase, and N sampling points are obtained within [t₀, (t₀+T)] time interval, T is power frequency period of input current for the rectifier.

9. The rapid online diagnosis method of open-circuit fault for high-power rectifier of claim 2, being characterized in that: calculation formulas of direct current components of three phase input electric current are as follows:
$$\{ \begin{matrix}{id}_{a} ( {t}_{0} + T ) = \frac{1}{N} {\sum }_{k = 1}^{N} {i}_{a} ( k ) \\ {id}_{b} ( {t}_{0} + T ) = \frac{1}{N} {\sum }_{k = 1}^{N} {i}_{b} ( k ) \\ {id}_{c} ( {t}_{0} + T ) = \frac{1}{N} {\sum }_{k = 1}^{N} {i}_{c} ( k )\end{matrix}$$
wherein t₀ is present moment, idₐ(t₀+T), id_{b}(t₀+T) and id_{c}(t₀+T) are direct current components of three phase input electric current, T is power frequency period of input current for the rectifier, iₐ(k) is electric current of the k-th sampling point of phase A, i_{b}(k) is electric current of the k-th sampling point of phase B, i_{c}(k) is electric current of the k-th sampling point of phase C, N is the total number of sampling point-in each phase, and N sampling points are obtained within [t₀, (t₀+T)] time interval.

10. The rapid online diagnosis method of open-circuit fault for high-power rectifier of claim 1, being characterized in that: m is 0.25, and n is 0.5.
